(19) United States
(12) Patent Application Publication
(10) Pub. No.: US 2015/0263243 A1
(43) Pub. Date: Sep. 17, 2015

(54) LIGHT EMITTING DEVICE

(71) Applicant: KABUSHIKI KAISHA TOSHIBA, Tokyo (JP)

(72) Inventors: Keiji NAKAGAWA, Kanazawa Ishikawa (JP); Hiroshi KOIZUMI, Hiratsuka Kanagawa (JP)

(21) Appl. No.: 14/475,514

(22) Filed: Sep. 2, 2014

(30) Foreign Application Priority Data
Mar. 14, 2014 (JP) 2014-051247

(51) Int. Cl. H01L 33/50; H01L 33/60; H01L 33/58

(52) U.S. Cl. CPC H01L 33/504; H01L 33/58; H01L 33/60

(57) ABSTRACT

A light emitting device includes a light emitting body having a first surface, a second surface opposed to the first surface, and a side surface connecting the first surface and the second surface. A first wavelength converter is on the side surface and includes a first material that is excited by a primary light emitted from the light emitting body and emits a secondary light at second wavelength different from a first wavelength of the primary light. A second wavelength converter is on the first surface and includes a second fluorescent material that is excited by the primary light and emits a light at a third wavelength different from the first wavelength and the second wavelength. The second wavelength converter is disposed on the first surface such that the first wavelength converter is not between the second wavelength converter and the first surface.

### CROSS-REFERENCE TO RELATED APPLICATION

This application is based upon and claims the benefit of priority from Japanese Patent Application No. 2014-051247, filed Mar. 14, 2014, the entire contents of which are incorporated herein by reference.

### FIELD

Embodiments described herein relate generally to a light emitting device.

### BACKGROUND

A light emitting device under development in recent years includes a light emitting body such as a light emitting diode and a fluorescent material used in combination with each other. The fluorescent material in such a device is excited by light emitted from the light emitting body and emits light at a wavelength different from the excitation light from the light emitting body. This type of light emitting device can be a white light source when containing a combination of a blue light emitting diode and a yellow fluorescent material, a red fluorescent material, or a green fluorescent material, for example. White light sources are used for a wide variety of purposes, and are often required to have different color properties for meeting these respective purposes.

### DESCRIPTION OF THE DRAWINGS

FIG. 1 is a cross-sectional view schematically illustrating a light emitting device according to a first embodiment.

FIG. 2 is a partial cross-sectional view schematically illustrating an operation of the light emitting device according to the first embodiment.

FIGS. 3A through 3D are graphs illustrating light emission characteristics of the light emitting device according to the first embodiment.

FIGS. 4A and 4B are graphs illustrating other light emission characteristics of the light emitting device according to the first embodiment.

FIG. 5 is a cross-sectional view schematically illustrating a light emitting device according to a modified example of the first embodiment.

FIG. 6 is a cross-sectional view schematically illustrating a light emitting device according to another modified example of the first embodiment.

FIG. 7 is a cross-sectional view schematically illustrating a light emitting device according to a further modified example of the first embodiment.

FIG. 8 is a cross-sectional view schematically illustrating a light emitting device according to a second embodiment.

### DETAILED DESCRIPTION

There is, in general, a demand for a light emitting device capable of controlling emission color with ease, and raising light emission output. An embodiment provides a light emitting device with improved controllability of emission color and light emission output.

According to one embodiment, a light emitting device includes a light emitting body, a first wavelength converter, and a second wavelength converter. The light emitting body has a first surface, a second surface disposed opposed to the first surface, and a side surface connecting the first surface and the second surface. The first wavelength converter is provided around the light emitting body along the side surface, and contains a first fluorescent material excited by primary light emitted from the light emitting body and emitting first light having a wavelength different from a wavelength of the primary light. The second wavelength converter is provided on the first surface, is disposed such that the first wavelength converter is not present between the second wavelength converter and at least a portion of the first surface, and contains a second fluorescent material emitting second light having a wavelength different from the wavelength of the primary light emitted from the light emitting body and the wavelength of the first light emitted from the first fluorescent material.

Exemplary embodiments are hereinafter described with reference to the drawings. The same reference numbers are given to substantially similar components in the respective figures. The same detailed explanation of similar components is not repeated, and, in general, only differences between examples are described. The respective figures are only schematic or conceptual illustrations. The relationships between the thicknesses and widths of respective components, the ratios of the sizes of respective components, and other conditions are not necessarily the same as the actual ones. The dimensions and ratios of some components in one figure may be expressed differently from those in other figures.

### First Embodiment

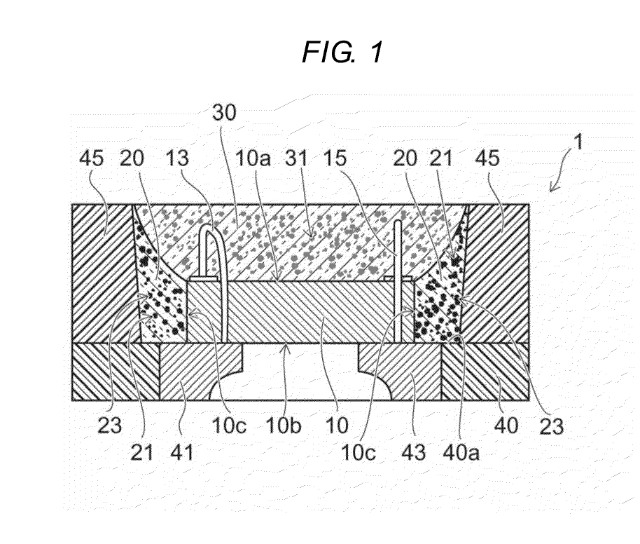

FIG. 1 is a cross-sectional view schematically illustrating a light emitting device 1 according to a first embodiment.

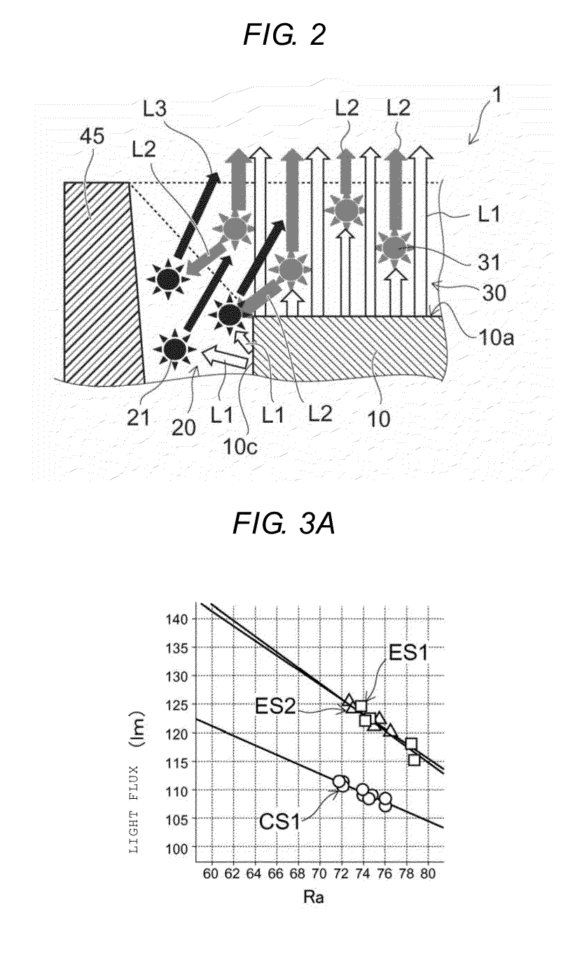

FIG. 2 is a partial cross-sectional view schematically illustrating an operation of the light emitting device 1 according to the first embodiment.

The light emitting device 1 illustrated in FIGS. 1 and 2 includes a light emitting body 10, a first wavelength converter 20, and a second wavelength converter 30.

In this first embodiment, the light emitting body 10 is a light emitting diode (LED) formed by a gallium nitride based semiconductor that emits blue light having an emission spectrum peak in the wavelength range from 430 nm to 480 nm. The light emitting body 10 has a first surface 10a, a second surface 10b disposed opposed to the first surface 10a, and a side surface 10c connecting the first surface 10a and the second surface 10b.

The first wavelength converter 20 is provided around the light emitting body 10 along the side surface 10c. The wavelength converter 20 includes a first fluorescent material 21. The first fluorescent material 21 is excited by primary light emitted from the light emitting body 10, and emits light (secondary light) having a wavelength different from the wavelength of the primary light. The peak wavelength of fluorescence spectrum emitted from the first fluorescent material 21 is different from the peak wavelength of emission spectrum emitted from the light emitting body 10.

The second wavelength converter 30 is disposed on the first surface 10a. The second wavelength converter 30 is provided such that the first wavelength converter 20 is not present between the second wavelength converter 30 and at least a portion of the first surface 10a. The second wavelength converter 30 includes a second fluorescent material 31. The second fluorescent material 31 upon excitation emits light (secondary light) having a wavelength different from the wavelength of the primary light emitted from the light emitting body 10 and the wavelength of the secondary light emitted from the first fluorescent material 21.

The light emitting device 1 is now detailed with reference to FIGS. 1 and 2.

The light emitting body 10 is mounted in such that the second surface 10b faces towards base 40, for example. The base 40 is made of resin containing titanium oxide or the like that is capable of reflecting light emitted from the light emitting body 10. The base 40 is comprised of a so-called “white resin,” for example. The base 40 includes frames 41 and 43 made of molded white resin.

An upper surface 40a of the base 40 has an area on which the light emitting body 10 is mounted (mount bed). The mount bed is formed such that the frames 41 and 43 are exposed through the mount bed. It is preferable that the upper surfaces of the frames 41 and 43 exposed through the mount bed are coated with silver plating or the like so that light emitted from the light emitting body 10 may be reflected at these surfaces. A reflecting member (hereinafter referred to as “reflector 45”) is provided on the base 40. As depicted, the reflector 45 is opened to above (i.e., does not cover first surface 10a), and surrounds, in a plane parallel to the first surface 10a, the light emitting body 10 mounted on the mount bed. The reflector 45 is made of white resin, for example. According to this structure, a recess is formed on the upper surface 40a of the base 40, and the inner surface of the recess reflects light emitted from the light emitting body 10. It is preferable that the inner surface of the reflector 45 is configured to expand toward above, for example. That is, reflector 45 as inner walls/surfaces (walls facing or on the same side as the light emitting body 10) which are outwardly inclined from the light emitting body 10 such that width of the recess in reflector 45 increases with increasing perpendicular distance from the mount bed.

The light emitting body 10 is mounted on the upper surface 40a of the base 40. Metal wires 13 and 15 are bonded between an electrode of the light emitting body 10 and the frame 41, and between another electrode of the light emitting body 10 and the frame 43, respectively. Accordingly, the light emitting body 10 is electrically connected with the frames 41, 43 via metal wires.

As illustrated in FIG. 1, the first wavelength converter 20 provided between the light emitting body 10 and the reflector 45 covers the side surface 10c of the light emitting body 10. The term “covers” in this context is not limited to the condition in which the “covering material” comes into direct contact with the “covered material”, but includes the condition in which the “covering material” covers the “covered material” with another element (or elements) interposed between the “covering material” and the “covered material”.

The first wavelength converter 20 is made of silicone resin which contains the fluorescent material 21 and scatterers 23 in such a condition that both the components 21, 23 are dispersed in the silicone resin, for example. The first wavelength converter 20 is injected into the space between the light emitting body 10 and the reflector 45 using a dispenser, for example, and fills the corresponding space.

The first fluorescent material 21 has an emission peak in the wavelength range longer than 600 nm, for example. The first fluorescent material 21 is a red or orange fluorescent material formed by a nitride fluorescent material. The scatterers 23 scatter light emitted from the light emitting body 10. The scatterers (scattering material) 23 are formed by silica fillers, for example.

The second wavelength converter 30 is made of silicone resin containing the second fluorescent material 31 dispersed therein, for example. The second wavelength converter 30 is provided on the first surface 10a of the light emitting body 10 and covers at least a portion of the first surface 10a. The second wavelength converter 30 may be formed by potting or other methods.

As illustrated in FIG. 1, it is preferable that the second wavelength converter 30 covers the first surface 10a without the presence of the first wavelength converter 20 between the second wavelength converter 30 and the first surface 10a. For example, while the periphery of the first surface 10a connecting with the side surface 10c may be covered by the first wavelength converter 20, it is preferable that at least a portion of the central area of the first surface 10a is covered only by the second wavelength converter 30 without the presence of the first wavelength converter 20 between the second wavelength converter 30 and the first surface 10a.

It is preferable that the second wavelength converter 30 contains a second fluorescent material 31 which emits fluorescent light having a wavelength shorter than the wavelength of the first fluorescent material 21, for example. The second fluorescent material 31 is formed by yellow fluorescent material or green fluorescent material having emission peak in the wavelength range from 500 nm to 600 nm, or both of the yellow and green fluorescent materials, for example. The second fluorescent material 31 may be formed by YAG fluorescent material or nitride fluorescent material, for example.

As illustrated in FIG. 2, primary light L1 emitted from the first surface 10a of the light emitting body 10 is partially absorbed by the second fluorescent material 31 during the process of traveling through the interior of the second wavelength converter 30. The second fluorescent material 31 excited by the primary light L1 emits secondary light L2. Accordingly, the primary light L1 and the secondary light L2 are emitted outwardly of the first surface 10a of the light emitting body 10 (in the direction from the light emitting body 10 toward the second wavelength converter 30).

On the other hand, the primary light L1 emitted from the side surface 10c of the light emitting body 10 is absorbed by the first fluorescent material 21 during the process of traveling through the interior of the first wavelength converter 20. The first fluorescent material 21 excited by the primary light L1 emits secondary light L3. The primary light L1 emitted from the side surface 10c travels in the transverse direction, and may be reflected by the reflector 45. The primary light traveling through the interior of the first wavelength converter 20 is also scattered by the scatterers 23. Accordingly, the optical path length of the transversely emitted primary light L1 increases, which causes the proportion of the transversely emitted primary light L1 absorbed by the first fluorescent material 21 to rise.

The density of the scatterers 23 dispersed in the first wavelength converter 20 may be raised to such a level that the fluorescent material 21 fills the spaces between the scatterers 23. In this case, the excitation efficiency of the first fluorescent material 21 further may improve. Moreover, with the rise of the density of the scatterers 23, the light traveling in the direction toward the base 40 may decrease. In this condition, the light absorbed by the frames 41 and 43 and others may decrease, wherefore the light emission output from the light emitting device 1 may increase.

As illustrated in FIG. 2, the secondary light L2 emitted from the second fluorescent material 31 also travels toward the first wavelength converter 20, and is absorbed by the first fluorescent material 21. Accordingly, the first fluorescent material 21 may be excited by both the primary light L1 and the secondary light L2, and thus emits secondary light L3.

According to this first embodiment, the first fluorescent material 21 and the second fluorescent material 31 are disposed separately from each other. More specifically, the first fluorescent material 21 is disposed on the side surface side of the light emitting body 10, while the second fluorescent material 31 is disposed on the upper surface of the light emitting body 10. This arrangement limits mutual light absorption between the two fluorescent materials, and allows efficient excitation of the fluorescent materials contained in the respective wavelength converters. Moreover, the light emission output from the light emitting device 1 becomes higher than the light emission output from a structure which includes a mixed arrangement of the first fluorescent material 21 and the second fluorescent material 31.

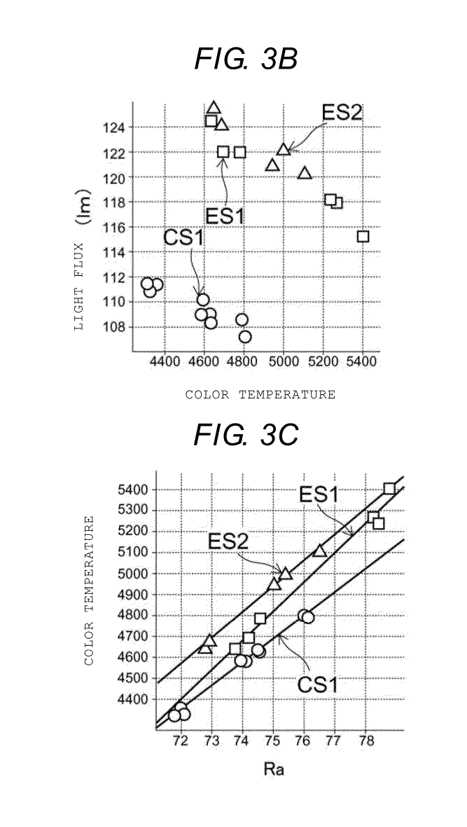

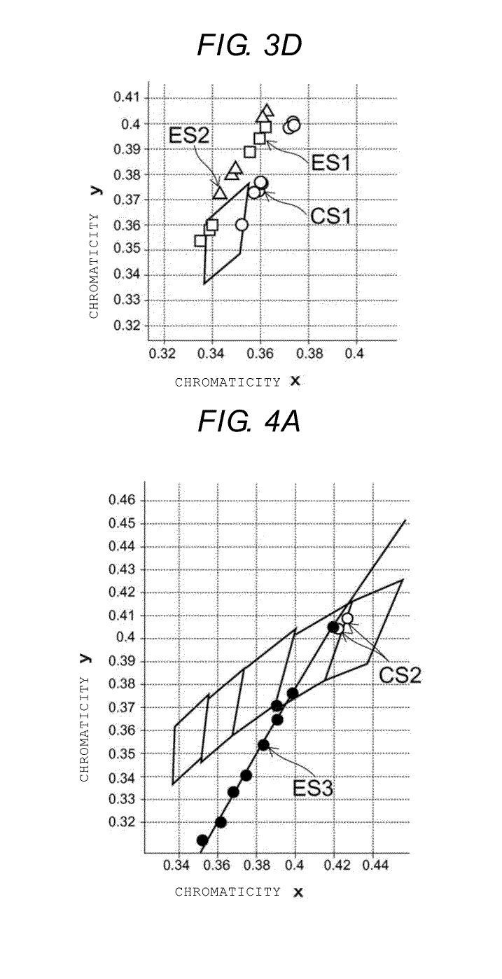

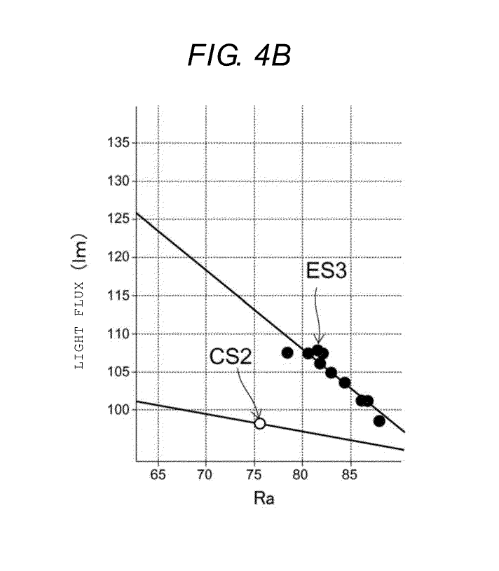

The light emission characteristics of the light emitting device 1 are now discussed with reference to FIGS. 3A through 4B.

FIGS. 3A through 4B are graphs illustrating the light emission characteristics of the light emitting device 1 according to the first embodiment.

FIG. 3A is a graph illustrating the relationship between general color rendering index (CRI) Ra and light flux. The horizontal axis indicates general color rendering indexes Ra, while the vertical axis indicates light flux (lumen: lm).

Data ES1 (square) and ES2 (triangle) shown in FIG. 3A are data obtained from the light emitting device 1 according to this first embodiment. Data CS1 (circle) is data obtained from a light emitting device of a comparison example lacking features of the first embodiment. The light emitting device according to the comparison example includes the light emitting body 10 covered with a single resin layer (wavelength converter), and a mixture of red fluorescent material and yellow fluorescent material dispersed in the resin layer. The data ES1 is obtained when the concentration of the first fluorescent material 21 (red fluorescent material) contained in the first wavelength converter 20 is set to 20% by weight. The data ES2 is obtained when the concentration of the red fluorescent material contained in the first wavelength converter 20 is set to 15% by weight. The wavelength converter of the data CS1 contains the same amount of fluorescent material as that of the wavelength converter of the data ES2. Each data in FIG. 3A indicates a change of light flux observed in each of samples containing different amounts of the second fluorescent material 31. These general explanations are applicable to data shown in FIGS. 3B through 3D as well.

As may be seen from FIG. 3A, each data indicates that light flux decreases as the index Ra increases. According to the graph, no substantial difference is found in the light flux between the data ES1 and ES2. On the other hand, the comparison between the data ES1 and ES2 and the data CS1 shows that each light flux of the data ES1 and ES2 is approximately 13% higher than the light flux of the data CS1 at the same Ra.

FIG. 3B is a graph illustrating the relationship between color temperatures and light flux. The horizontal axis indicates color temperatures, while the vertical axis indicates light flux (lumen: lm). The respective data indicate that light flux decreases as the color temperature rises. No substantial difference is found in the light flux between the data ES1 and ES2. On the other hand, the comparison between the data ES1 and ES2 and the data CS1 shows that each light flux of the data ES1 and ES2 is approximately 13% higher than the light flux of the data CS1 at the same color temperature.

FIG. 3C is a graph illustrating the relationship between general color rendering indexes Ra and color temperatures. The horizontal axis indicates general color rendering indexes Ra, while the vertical axis indicates color temperatures. The respective data indicate that the color temperature rises as the index Ra increases. It is also found that the relationship between the general color rendering index Ra and the color temperature makes a substantially linear change for each of the data ES1, ES2, and CS1. This means that the controllability of the color temperature and the index Ra is maintained in the structure disposing the first fluorescent material 21 and the second fluorescent material 31 separately from each other, in comparison with the structure containing the mixture of the first fluorescent material 21 and the second fluorescent material 31.

FIG. 3D is a graph illustrating the chromaticity (x, y) of emission light. The horizontal axis indicates chromaticity coordinates x, while the vertical axis indicates chromaticity coordinates y. As may be seen from the graph, each chromaticity of the data ES1, ES2, and CS1 makes a linear change. This means that the controllability of the emission color is maintained in the structure disposing the first fluorescent material 21 and the second fluorescent material 31 separately from each other, in comparison with the structure containing the mixture of the two fluorescent materials 21 and 31.

FIG. 4A is another graph illustrating the chromaticity (x, y) of emission light. The horizontal axis indicates chromaticity coordinates x, while the vertical axis indicates chromaticity coordinates y.

FIG. 4B is a graph illustrating the relationship between general color rendering indexes Ra and light flux. The horizontal axis indicates general color rendering indexes Ra, while the vertical axis indicates light flux (lumen: lm).

Data ES3 (filled circle) indicated in each of FIGS. 4A and 4B is obtained when the concentration of the first fluorescent material (here, a red fluorescent material) contained in the first wavelength converter 20 is set to 30% by weight. On the other hand, the wavelength converter of data CS2 contains the same amount of fluorescent material as that of the fluorescent material of the data ES3.

As may be seen from FIG. 4A, the chromaticity of the data ES3 makes a linear change, illustrating that the controllability of the emission color is maintained. On the other hand, as may be seen from FIG. 4B, light flux decreases as the index Ra increases. In addition, light flux of the data ES3 is approximately 15% higher than light flux of the data CS2 at the same Ra.

According to the first embodiment discussed above, the first fluorescent material 21 and the second fluorescent material 31 are disposed separately from each other in the transverse direction with respect to the light emission direction (direction from the light emitting body 10 toward the second wavelength converter). This structure prevents mutual light absorption between the respective fluorescent materials, thereby increasing the light emission efficiencies of the respective fluorescent materials. Moreover, the scatterers 23 dispersed in the first wavelength converter positioned on the side surface side of the light emitting body 10 increase the excitation efficiency of the first fluorescent material. Furthermore, this structure improves the light emission output of the light emitting device 1 while maintaining the controllability of the emission color. In addition, light emitted from the light emitting device 1 does not exhibit color non-uniformity, color breakup or other problems even in the structure disposing the first fluorescent material 21 and the second fluorescent material 31 separately from each other. In other words, the light emitting device 1 may achieve more uniform light emission.

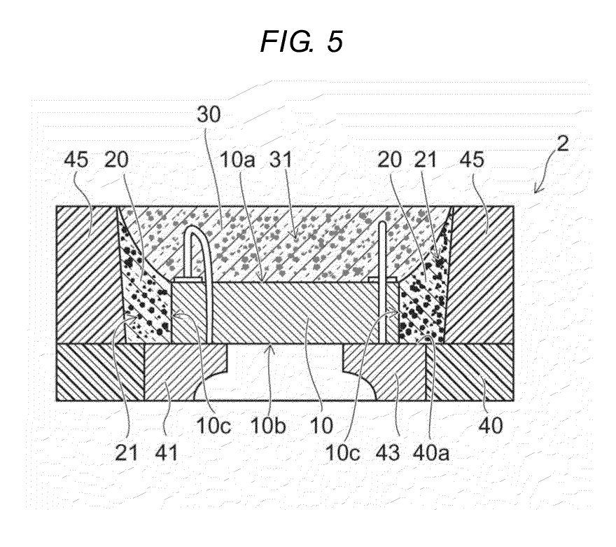

Hereinafter described with reference to FIGS. 5 through 7 are light emitting devices 2 through 4 according to modified examples of the first embodiment. In the respective modified examples, the advantages provided by the light emitting device 1 are similarly provided by components identical or similar to the corresponding components of the light emitting device 1.

FIG. 5 is a cross-sectional view schematically illustrating the light emitting device 2 according to a modified example of the first embodiment. The first wavelength converter 20 of the light emitting device 2 contains the first fluorescent material 21, but does not contain the scatterers 23. According to this example, the primary light L1 emitted from the light emitting body 10 and the secondary light L2 emitted from the second fluorescent material 31 travel through the interior of the first wavelength converter 20 while being reflected by the inner surface of the reflector 45 and the upper surface 40a of the base 40. Accordingly, the probability that the primary light L1 and the secondary light L2 are absorbed by the first fluorescent material 21 increases, whereby the excitation efficiency of the first fluorescent material 21 may improve.

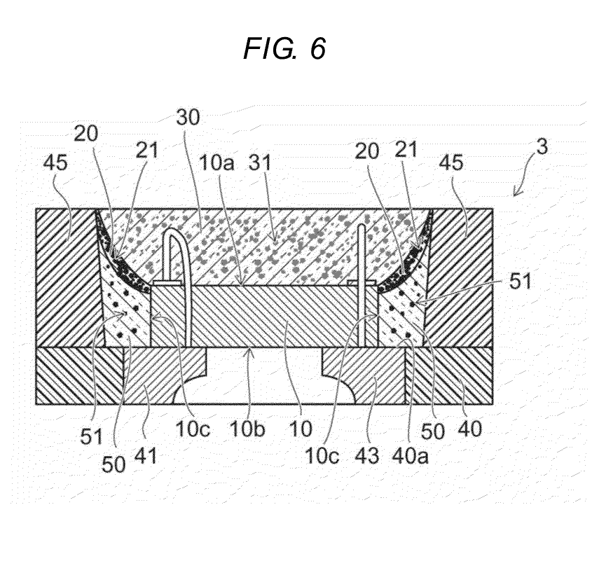

FIG. 6 is a cross-sectional view schematically illustrating the light emitting device 3 according to another modified example of the first embodiment. According to the light emitting device 3, a transparent resin layer 50 is provided between the light emitting body 10 and the reflector 45, and surrounds the side surface 10c of the light emitting body 10. The transparent resin layer 50 transmits the primary light L1 emitted from the light emitting body 10, the secondary light L2 emitted from the second fluorescent material 31, and the secondary light L3 emitted from the first fluorescent material 21. The transparent resin layer 50 contains scatterers 51 made of silica fillers, titanium oxide or other material.

The second wavelength converter 30 is provided on the first surface 10a of the light emitting body 10. The first wavelength converter 20 is provided between the second wavelength converter 30 and the transparent resin layer 50, and surrounds the light emitting body 10.

According to this example, the primary light L1 emitted from the side surface 10c of the light emitting body 10 travels toward the first wavelength converter 20 while scattered by the scatterers 51 and reflected by the reflector 45 and the upper surface 40a of the base 40. The first fluorescent material 21 contained in the first wavelength converter 20 is efficiently excited by the primary light L1 from the transparent resin layer 50, and the secondary light L2 emitted from the second fluorescent material 31 of the second wavelength converter 30 side. This structure may improve the light emission output from the light emitting device 3.

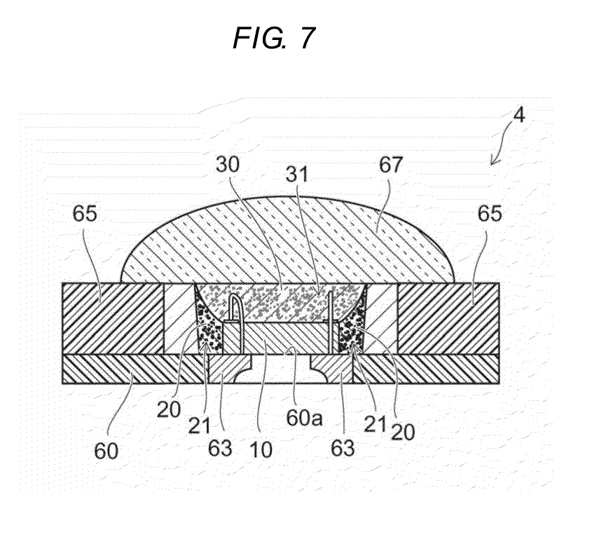

FIG. 7 is a cross-sectional view schematically illustrating the light emitting device 4 according to a further modified example of the first embodiment. According to the light emitting device 4, the light emitting body 10 is mounted on a base 60. The base 60 includes frames 61, 63, and a reflector 65 surrounding the light emitting body 10. Each of the base 60 and the reflector 65 contains a material reflecting light emitted from the light emitting body 10 (primary light).

The light emitting body 10 is mounted on an upper surface 60a of the base 60. The first wavelength converter 20 is provided between the side surface 10c of the light emitting body 10 and the reflector 65. The second wavelength converter 30 is provided on the first surface 10a of the light emitting body 10.

According to this example, there is further provided a lens 67 which covers a portion of the second wavelength converter 30 and a portion of the reflector 65. The lens 67 is made of transparent resin, for example. The lens 67 converges the primary light emitted from the light emitting body 10, and the secondary lights emitted from the first fluorescent material 21 and the second fluorescent material 31. Accordingly, the light emitting device 4 may control the orientation characteristics of the device 4 using the lens 67.

### Second Embodiment

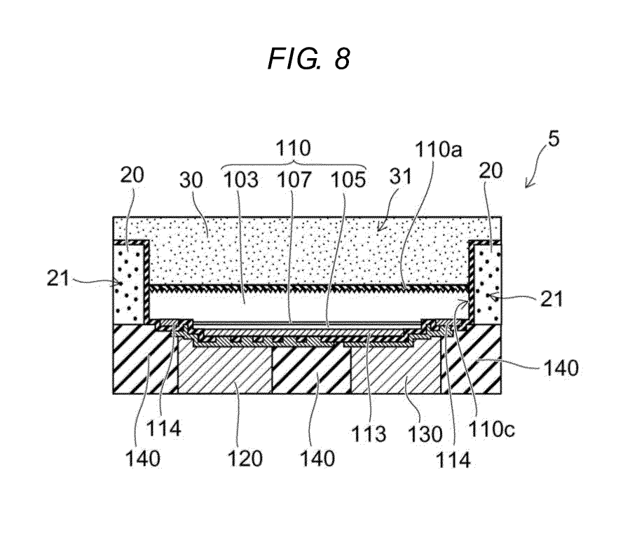

FIG. 8 is a cross-sectional view schematically illustrating a light emitting device 5 according to a second embodiment.

The light emitting device 5 includes a light emitting body 110, the first wavelength converter 20 surrounding a side surface 110c of the light emitting body 110, and the second wavelength converter 30 provided on a first surface 110a of the light emitting body 110.

The light emitting body 110 includes an n-type semiconductor layer 103, a p-type semiconductor layer 105, and a light emitting layer 107. The light emitting layer 107 is disposed between the n-type semiconductor layer 103 and the p-type semiconductor layer 105.

A resin layer 140, a p-electrode 120, and an n-electrode 130 are provided on a second surface of the light emitting body 110 on the side opposite to the first surface 110a side of the light emitting body 110. The p-electrode 120 penetrates the resin layer 140, and electrically connects with the p-type semiconductor layer 105. The n-electrode 130 penetrates the resin layer 140, and electrically connects with the n-type semiconductor layer 103.

In the light emitting body 110, when voltage is applied between the p-electrode 120 and the n-electrode 130, current flows between the p-electrode 120 and the n-electrode 130. As a result, the light emitting layer 107 of the light emitting body 110 emits light. The light from the light emitting layer 107 is emitted to the outside as primary light.

The first wavelength converter 20 is made of resin, for example, and contains the first fluorescent material 21. The second wavelength converter 30 is a resin layer covering the first surface 110a and the first wavelength converter 20, and containing the second fluorescent material 31, for example.

According to this example, the primary light emitted from the side surface 110c of the light emitting body 110 travels through the interior of the first wavelength converter 20, and excites the first fluorescent material 21. On the other hand, the primary light emitted from the first surface 110a of the light emitting body 110 travels through the interior of the second wavelength converter 30, and excites the second fluorescent material 31. The structure which disposes the first fluorescent material 21 and the second fluorescent material 31 separately from each other prevents mutual light absorption between the respective fluorescent materials, thereby efficiently exciting the respective fluorescent materials. Accordingly, the light emission efficiency of the light emitting device 5 may improve.

A light emitting device provided according to the embodiments is not limited to the light emitting devices 1 through 5 according to the first embodiment and the second embodiment described and depicted herein. Various embodiments and examples may be combined with each other when feasible. For example, each of the first fluorescent material 21 and the second fluorescent material 31 may contain a plurality of types of fluorescent materials. For example, the first fluorescent material 21 may contain red fluorescent material and orange fluorescent material, while the second fluorescent material 31 may contain yellow fluorescent material and green fluorescent material.

The primary light emitted from each of the light emitting bodies 10, 110 is not limited to blue light, but may be ultraviolet light, for example. When the primary light is ultraviolet light, it is preferable that the second wavelength converter 30 contains blue fluorescent material, for example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A light emitting device, comprising:
a light emitting body having a first surface, a second surface opposed to the first surface, and a side surface connecting the first surface and the second surface;
a first wavelength converter on the side surface, and including a first fluorescent material that is excited by a primary light emitted from the light emitting body and emits a first light having a second wavelength different from a first wavelength of the primary light; and
a second wavelength converter that is on the first surface and including a second fluorescent material that is excited by the primary light and emits a second light having a third wavelength different from the first wavelength and the second wavelength, wherein the second wavelength converter is disposed on a portion of the first surface such that the first wavelength converter is not between the second wavelength converter and the portion of the first surface.

2. The device according to claim 1, wherein a peak wavelength in the first light emitted by the first fluorescent material is longer than a peak wavelength in the second light emitted by the second fluorescent material.

3. The device according to claim 1, wherein the first wavelength converter includes scatterers that scatter the primary light.

4. The device according to claim 1, further comprising:
a reflecting member surrounding the light emitting body in a plane that is parallel to the first surface and reflects the primary light, the reflecting member including a recess in which the first wavelength converter is disposed, wherein
the first wavelength converter is provided between the light emitting body and the reflecting member.

5. The device according to claim 1, further comprising:
a base on a second surface side of the light emitting body, and being reflective of the primary light, wherein the light emitting body is mounted on the base.

6. The device according to claim 1, wherein the first fluorescent material is excited by the second light.

7. The device according to claim 1, further comprising a lens on a surface of the second wavelength converter opposite the first surface.

8. The device according to claim 1, wherein the first fluorescent material is evenly dispersed in the first wavelength converter.

9. The device according to claim 1, wherein a concentration of first fluorescent material is higher at an interface between the first wavelength converter and the second wavelength converter than a concentration of the first fluorescent material in a portion of the first wavelength converter away from the interface.

10. The device according to claim 9, wherein the first wavelength converter includes scattering material that scatters the primary light.

11. The device according to claim 1, wherein the first wavelength converter is a resin material.

12. The device according to claim 1, wherein the second wavelength converter is a resin material.

13. A light emitting device, comprising:
a light emitting body which emits a light at a primary wavelength from a first surface and has a second surface opposite the first surface and mounted to a base;
a reflector body surrounding the light emitting body in a plane parallel to the second surface and extending in a direction perpendicular to the second surface for a distance that is greater than a distance between the first and second surfaces in the direction perpendicular to the second surface;
a first resin material disposed between the reflector body and the light emitting body and including a first material absorbing light at the primary wavelength and emitting light at a first wavelength different from the primary wavelength; and
a second resin material disposed on the first surface of the light emitting body and including a second material absorbing light at the primary wavelength and emitting light at a second wavelength different from the primary wavelength and the first wavelength, wherein
the first resin material is between the second resin material and the reflector body.

14. The device according to claim 13, wherein the first resin material includes a scattering material therein that scatters light at the primary wavelength.

15. The device according to claim 13, wherein the first material is evenly dispersed in the first resin.

16. The device according to claim 13, wherein a concentration of first material is higher at an interface between the first resin material and the second material than a concentration of the first material in a portion of the first resin material away from the interface.

17. The device according to claim 13, further comprising:
a lens disposed on the first material and the reflector body.

18. A light emitting device, comprising:
a light emitting body having a first surface in a first plane, a second surface in a second plane parallel to the first plane, and a side surface extending between the first and second planes;
a first wavelength converter adjacent to the side surface and extending beyond the first surface in a first direction intersecting the first plane; and
a second wavelength converter on the first surface and extending in a direction orthogonal to the first surface, wherein
the first wavelength converter includes a first material that absorbs light at a primary wavelength emitted by the light emitting body and emits light a first wavelength different from the primary wavelength, and
the second wavelength converter includes a second material that absorbs light at the primary wavelength and emits light at a second wavelength different from the primary wavelength and the first wavelength.

19. The light emitting device according to claim 18, wherein a first material emits light at the first wavelength upon excitation by light at the second wavelength.

20. The light emitting device according to claim 18, wherein the first wavelength converter comprises a first resin.
